(19) United States
(12) Patent Application Publication
(10) Pub. No.: US 2008/0216306 A1
(43) Pub. Date: Sep. 11, 2008

(54) Resistor Device and Method of Manufacturing the Same

(76) Inventor: Koji Fujimoto, Nagano (JP)

Correspondence Address: VON SIMSON & CHIN, 62 WILLIAM STREET, 6TH FLOOR, NEW YORK, NY, 10005, US

(21) Appl. No.: 12/044,829

(22) Filed: Mar. 7, 2008

(30) Foreign Application Priority Data
Mar. 9, 2007 (JP) 2007-059654

(51) Int. Cl. H01C 17/28; G01R 31/28; B23K 26/00

(52) U.S. Cl. 29/619; 29/593; 219/121.68

(57) ABSTRACT

The present invention is to provide a method of trimming during short time without any difficulty of controlling a device for trimming and a trimming device having a simple structure. The method of manufacturing a resister device comprises: trimming a resister element 5 including a resister film 4 in order to adjust a resister value of the resister element 5, the resister film 4 contacting a pair of electrodes 3 for a resister formed on a substrate 2. A region of the substrate located in a position of a side portion 6 and along with the resister film 4 is heated in the trimming, the position being on a surface where the electrodes 3 for a resister and the resister film 4 are formed. The heating is performed by laser beam irradiation. The side portion 6 is irradiated by a laser beam to form a concave portion 7.

### CROSS REFERENCES TO RELATED APPLICATIONS

This application is based on Japanese Patent Application No. 2007-59654 filed on Mar. 9, 2007, the contents of which are hereby incorporated by reference.

### BACKGROUND OF THE INVENTION

1. Technical Field

The present invention relates to a resister device and a method of manufacturing thereof.

2. Related Art

Japanese unexamined patent publication 5-291012 discloses a technology of arranging (trimming) a resistance value of a resister element. The resister element includes a resister film contacting a pair of electrodes for a resister formed on a substrate. In trimming, a surface of the substrate is irradiated with a laser beam and heated. This surface is opposed to the other surface where the resister film is formed. Further, Japanese unexamined patent publication 2004-363528 discloses heating a surface of a resister film by irradiating it with a weak laser beam not so as to form a groove in a resister film.

When heating the surface of the substrate opposed to other surface where the resister film is formed, there are frequent cases in which a trimming prove for measuring a resistance value in trimming is contacted to other surface in which a resister film is formed and such other surface is irradiated with a laser beam. In such case, a structure of a device for trimming becomes complicated and it becomes difficult to control the device.

Further, in case of heating a surface of a resister film by irradiating it with a wave-like weak laser beam, it takes long time to trim the film if there is large difference between a resistance value without trimming and a target value for trimming. Further, a weak laser beam should be applied to a resister film in order to avoid deformation of the resister film and formation of a groove if the beam is strong. But, it is difficult to stabilize such weak laser beam during irradiation.

### SUMMARY

An advantage of the present invention is to provide a method of trimming during short time without any difficulty of controlling a device for trimming and a trimming device having a simple structure.

According to a first aspect of the invention, a method of manufacturing a resister device includes: trimming a resister element in order to adjust a resistance value, the resister element including a resister film contacted with a pair of electrodes for a resister formed on a substrate. In the trimming, a region of the substrate is heated, the region being placed in a side portion of the resister film and along the resister film on the surface of the substrate where the resister film and the pair of electrodes for a resister are formed.

The first aspect of the invention includes the trimming process heating the surface of the substrate on which the resister film and the electrodes for a resister are placed. Hence, in this trimming, a surface of the substrate for contacting a trimming probe becomes the same surface of substrate for laser beam irradiation, making the structure of a trimming device simple and the device easily controlled. Further, the aspect of the invention can set higher temperature for heating, attaining short time trimming.

In the first aspect of the invention, heating may be performed by irradiating the resister device with a laser beam. This method can heat a minute region with high temperature.

Further, in the first aspect of the invention, a groove may be formed in the side portion with laser beam irradiation. The method can make the groove being a mark for completing the trimming. When forming an overcoating film on the surface of the resister film, the overcoating film is infiltrated into the groove, strengthening adhesiveness of the overcoating film with the substrate.

In the first aspect of the invention, the side portion of the resister film may be heated. This method constrains overheating one end of the resister film and dissipates heat to both ends of it.

Further, in the first aspect of the invention, the resister film may be formed on the substrate in a winding way and the side portion of the resister film may be placed at the outside end of the winding way. This method can restrain a drift, a fluctuation of the resistance value after trimming.

Further, in the first aspect of the invention, a part of the resister film may be removed in order to narrow a current path of the resister film in addition to the heating during trimming. This method can improve an accuracy of trimming. The reason is following: Trimming the resister film by heating normally makes the resistance value of the resister device having the resister film get to be low. On the other hand, trimming the resister film by removing the part of the resister film to narrow the current path makes the resistance value get to be high. Hence, in case of using the above two trimming methods, even if the resistance value exceeds a target value by making the resistance value before trimming approach the target value via one trimming method, such exceeded value can be corrected via other trimming method, improving the accuracy of trimming.

Further, in the first aspect of the invention, a part of the resister film may be removed before a region of the substrate being heated. Even if the resistance value exceeds a target value and becomes higher by removing a part of the resister film, the above method can correct the exceeded value by heating the resister film as trimming, improving the accuracy of trimming.

Further, in the first aspect of the invention, the resister film may be winded or the winding state may be accelerated by removing a part of the resister film. This method can easily attain forming the winding resister film, which is relatively difficult by other method.

According to a second aspect of the invention, a method of manufacturing a resister device comprises: trimming a plurality of resister elements via heating in order to adjust a resistance value of the resister elements that are formed on a large substrate and includes a resister film contacting a pair of electrodes for a resister. The trimming includes: obtaining an adjusted resister film via first trimming for adjustment by heating a side portion of the contact area of an un-adjusted resister film of which a resistance value is not adjusted, contacted with a substrate; obtaining other adjusted resister film via second trimming by heating a side portion of the un-adjusted resister film being formed on the large substrate and not adjacent to the adjusted resister film in order to adjust a resistance value; and repeating the second trimming.

According to the second aspect of the invention, the surface of the large substrate on which the electrode for a resister device and the resister film are formed, is heated during trimming. Hence, this method makes the surface of the large substrate contacted by a trimming prove be applied to the surface of the large substrate irradiated by a laser beam, avoiding complexity of a device for trimming and difficulty in controlling such device. Further, this method can set heating temperature high, trimming the device during short time. Further, this method trims the large substrate on which pluralities of the resister films are formed, making it possible to efficiently trim pluralities of the resister films. Further, in the second trimming, a part of large substrate that is an end of the un-adjusted resister film not being adjacent to the adjusted resister film is heated. This heating restrains fluctuation of the resistance value by re-heating the adjusted resister film.

According to a third aspect of the invention, a resister device comprises: a substrate, a pair of electrodes for a resister formed on the substrate, a resister film being contacted with the electrodes, and a concave portion being formed at a side portion of the resister film on a surface of the substrate on which the resister film is formed.

The third aspect makes the surface of the large substrate contacted by a trimming prove be applied to the surface of the large substrate irradiated by a laser beam, avoiding complexity of a device for trimming and difficulty in controlling such device. Further, a concave portion being formed in a side portion of the resister film can be formed as a trace by heating the resister film and trimming the resister element. In such case, this method can set heating temperature high, trimming the device during short time. When an overcoating film is formed on the surface of the resister film, the overcoating film is infiltrated into the concave portion, enhancing the adhesiveness of the overcoating film.

These above aspects of the invention can avoid the device of trimming to be complicated, easily control such device and trim the resister device during short time.

### BRIEF DESCRIPTION OF THE DRAWINGS

The invention will be described with reference to the accompanying drawings, wherein like numbers reference like elements.

FIGS. 1 (A), (B) and (C) are a plain view of a resister device regarding embodiments of the invention in which an overcoating film and a plated film are omitted. FIG. 1(A) shows a resister device regarding a first embodiment. FIG. 1(B) is a modification of the first embodiment. FIG. 1(C) shows a resister device regarding a second embodiment. FIG. 1 (D) shows a resister device regarding a third embodiment. FIG. 1(E) shows a resister device regarding a fourth embodiment.

FIGS. 2 (A) to (I) are a diagram showing a method of manufacturing the resister device regarding the first embodiment and ongoing processes from (A) to (I).

FIGS. 3 (A) to (C) are a diagram showing a trimming process in the method of manufacturing the resister device regarding the first embodiment and ongoing processes from (A) to (C).

### DESCRIPTION OF EXEMPLARY EMBODIMENTS

A resister device and a method of manufacturing the same according to a first, second, third and fourth embodiments are explained with referring to figures.

(Method of Manufacturing Resister Device of First Embodiment)

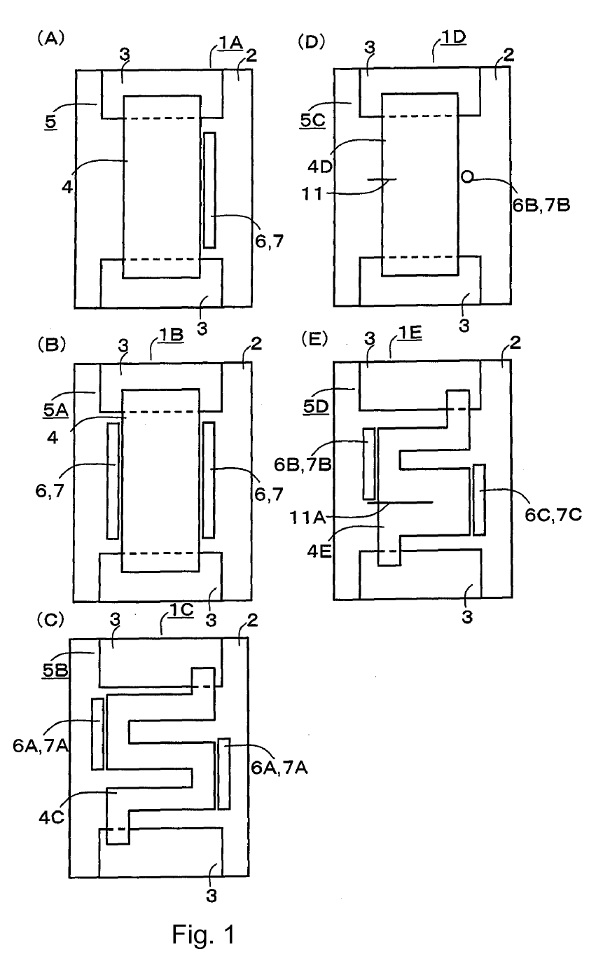

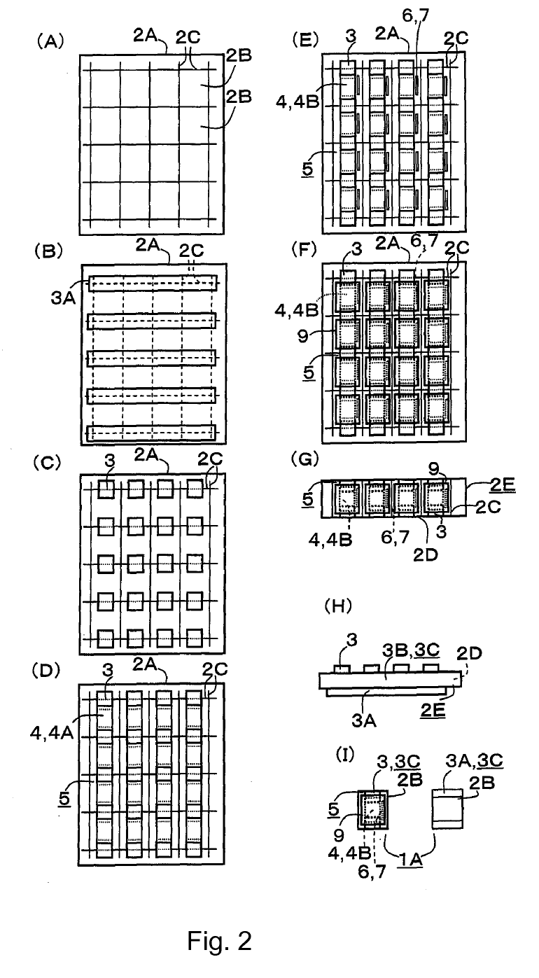

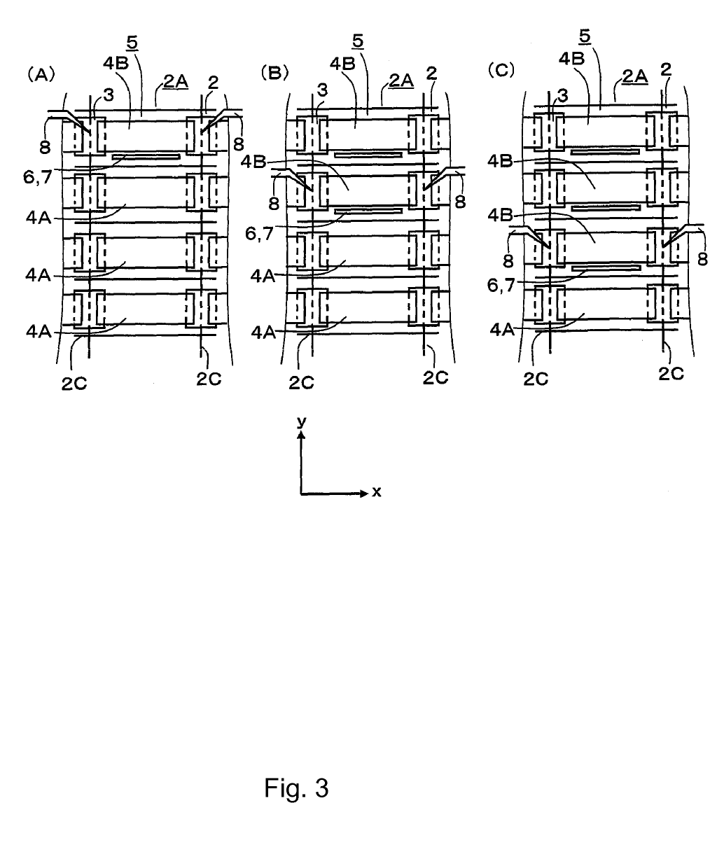

A method of manufacturing a resister device 1A is explained with referring to FIG. 1(A), FIGS. 2 (A) to (I) and FIGS. 3 (A) to (C). FIG. 1 (A) is a plain view of the resister device 1A in which an overcoat film and a plated layer described later are omitted. In the first embodiment, a method of manufacturing the resister device 1A includes a process for trimming a resister element 5 that has a resister film 4. The resister film 4 contacts a pair of electrodes 3 for a resister formed on one surface of a substrate 2. In the trimming process, a region of the substrate 2 is heated. Such region is located in a side portion 6 and along with the resister film 4 on a surface of the substrate where the electrodes 3 for a resister and the resister film 4 are placed. Such heating is performed by laser beam irradiation. This laser beam irradiation forms a concave portion 7 in the side portion 6.

More specifically, a method of manufacturing the resister device 1A according to the first embodiment includes a process for heating the resister element 5 that has a resister film 4 as trimming. The resister film 4 contacts the pair of electrodes 3 for a resister formed on one surface of a large substrate 2A shown in FIG. 2. In the trimming process, one surface of a large substrate 2A is trimmed with heating. The pair of electrodes 3 and the un-adjusted resister film 4A are placed on this surface with a side portion 6 which makes an un-adjusted resister film 4A contact with the large substrate 2A. Then, first trimming is completed to obtain an adjusted resister film 4B. Next, other area of the side portion 6 is heated and trimmed. This other area includes the un-adjusted resister film 4A formed on the large substrate 2A, but does not contact with the adjusted resister film 4B. Then, second trimming is repeated to obtain the other adjusted resister film. Then, the second trimming is completed to obtain other adjusted resister film 4B. The second trimming is repeated thereafter. Combination of the un-adjusted resister film 4A and the adjusted resister film 4B is marked as the resister film 4 hereafter if it is necessary.

FIGS. 2(A) to 2(I) show ongoing processes of a method of manufacturing the resister device 1A regarding the first embodiment. Detail processes are explained hereafter.

First, the large substrate 2A shown in FIG. 2(A) is prepared. The large substrate 2A is made of alumina ceramics. One surface of the large substrate 2A includes grooves 2C for partitioning which are horizontally and vertically intersected each other. One unit surrounded by grooves 2C for partitioning is a unit substrate 2B. The large substrate 2A is made of aluminum nitride or a resin with a glass fiber. In particular, aluminum nitride shows good heat radiation. Hence, this material urgently radiates heat generated by the resister film 4 and stored in the large substrate 2A. Accordingly, this material has an advantage of restraining fluctuation of the resister value of the trimmed resister element 5. The fluctuation is caused by heating the adjusted resister film 4B with heat stored in the large substrate 2A after completing trimming. Grooves 2C for partitioning may be installed depending on its necessity. For example, grooves 2C for partitioning are not necessary if the large substrate 2A is partitioned by using a dicing saw during a first and/or second partitioning process. Further, grooves 2C may include only one of horizontal and vertical directions without intersecting these directions. Otherwise, grooves 2C for partitioning may be installed on both two surfaces of the large substrate.

(Forming First Electrode)

FIG. 2(B) shows a backside electrode 3A formed on the surface where grooves 2C for partitioning are not formed on the large substrate 2A. In order to form the backside electrode 3A, a rectangular stripe made of metal glaze paste of silver powders is formed by a screen printing method and hardened. The rectangular stripe is placed in a way of crossing over both horizontal and vertical directions of grooves 2C for partitioning on the opposite surface of the substrate. FIG. 2(C) shows a pair of electrodes 3 formed on the surface where grooves 2C for partitioning are formed on the large substrate 2A. In order to form the pair of electrodes 3 for a resister, a rectangular stripe made of metal glaze paste of silver-palladium powders is formed by a screen printing method and hardened. The rectangular stripe crosses over only a horizontal direction of grooves 2C and is placed far from the adjacent electrode 3 for a resister. Here, the electrode 3 for a resister and the backside electrode 3A may be made of other electro conductive material such as nickel or epoxy or acryl electro conductive adhesive. But, these electrodes may be preferably made of alloy mainly composed of silver or gold since these materials have an advantage in anti-oxidation under quenching or heating with atmosphere and high conductivity. If the adjacent electrode 3 for a resister is short-circuited, an exact value of the resistance cannot be measured during the trimming process. The cause of such short circuit is a migration phenomenon where ionized metals are pulled by an electric field and moved under water. But, it is uneasy for silver-palladium alloy to generate such migration phenomenon so that such material is favorable for the electrode for a resister. Further, the electrode 3 for a resister and the backside electrode 3A may be formed by a thin film technology such as sputtering instead of a thick film technology such as a screen printing method.

(Forming Resister Film)

FIG. 2 (D) shows the resister film 4 formed after the above process. In order to form the resister film 4, a metal glaze paste of oxidized lutetium-metal (silver and the like) mixed powders is deposited by a screen printing method and hardened. The paste is deposited on the unit substrate 2B in a way of crossing over a part of a pair of electrodes 3 for a resister on the large substrate 2A. As the result, a single resister element 5 is formed on the unit substrate 2B. The resister element 5 includes the resister film 4 contacting a pair of electrodes 3 for a resister. The value of resistance of the resister element 5 is higher than the standard resistance value as a target for the resister device 1A by 10 to 15% and fluctuated. Such fluctuation is caused by difficulty in keeping high accuracy of resistance of the resister element 5 formed only by screen printing and hardening. Further, the resister film 4 is an un-adjusted resister film 4A at this stage. Here, the electrode 4 for a resister may be formed by a thin film technology such as sputtering instead of a thick film technology such as a screen printing method. Further, the electrical conductivity of the resister film 4 may be changed by adding resin materials including carbon or graphite powders and heating.

(Trimming)

FIG. 2(E) shows a state of heating the un-adjusted resister film 4A after the above process and trimming the resister element 5, namely completing the trimming. In order to trim the element, a region of the large substrate 2A is irradiated with a laser beam to form a stripe shape by a laser trimmer (a trimming device.) Such region is located in the position to be the side portion 6 and along with the resister film 4 and the end of it, but a little far from it. A concave portion 7 is formed by evaporating the side portion 6 with laser beam irradiation. As shown in FIGS. 3(A) to 3(C), during trimming, a resister value of the resister element 5 is measured by making a trimming probe 8 contact with a pair of electrodes 3. When the resistance value approaches a target as a standard value by heating and become higher than the target value by 5%, irradiation of a laser beam is stopped. Then, the resistance value reaches the target by remained heat.

Timing for stopping laser beam irradiation can appropriately be changed depending on the standard value of resistance and the condition of a laser beam output. For example, if the resistance value becomes higher than the target by 1, 2, 3 and 4%, irradiation of a laser beam may be stopped. Otherwise, the resister film may be irradiated with a laser beam until when the resistance value becomes the target. Further, the resistance value of the resister element 5 may become higher by heating depending on a material used for the resister film 4. In such case, the resister element 5 including the un-adjusted resister film 4A is formed with setting the resistance value lower than the target. Then, during trimming, irradiation of a laser beam is stopped when the resistance value becomes the target or lowers than the target. Here, a means for heating may not be limited to irradiation of laser beams. For example, an electric heater can be used. But, irradiation of laser beams is more favorable for heating a minute area and restrains thermal effect toward other adjacent resister element 5 in the large substrate 2A. Further, at the time of irradiation of laser beams, heating temperature (laser beam output) may be adjusted to the level of not forming the concave portion 7.

Further, it is impossible for the trimming device in the embodiment to irradiate a laser beam itself with a stripe shape. If the position irradiated with a laser beam is fixed, the shape of a region irradiated with a laser beam is approximately circular. Hence, in order to irradiate a laser beam with a stripe shape, the position irradiated with a laser beam is moved in a way that such position is overlapped with the area where a laser beam was previously irradiated with a circular shape. Then, the position is irradiated with a laser beam every moving. The speed of moving the position irradiated with a laser beam is appropriately changed depending on the standard of resistance of a resistor, the condition of a laser output and other process conditions. Here, irradiation of a laser beam may be continued while the position irradiated with a laser beam being moved. Further, any shapes of a region heated can be appropriately selected, not only limited to a stripe shape. But, there is a case when it is necessary to largely change the value of the resister element 5, or to restrict overheating a part of the resister film 4. In such case, a region irradiated with a laser beam is preferably a stripe area along with the end of the resister film 4 in order to restrain a damage of the resister film 4 due to overheating and disperse heated regions in the resister film 4. In order to further disperse heated areas in the resister film 4, an area irradiated by a laser beam is preferably two side portions 6 of the resister film 4 such as the resister device B shown in FIG. 1(B) which is a modification of the resister device A in the first embodiment.

FIGS. 3(A) to (C) show trimming a plurality of resister devices 5 formed on the large substrate 2A, ongoing from (A) to (C). First, as shown in FIG. 3 (A), the side portion 6 which is a area of contacting the un-adjusted resister film 4A with the large substrate 2A is trimmed via heating in order to obtain the adjusted resister film 4B. This process is called as the first trimming described before. Then, as shown in FIGS. 3 (B) and (C), the side portion 6 contacting the un-adjusted resister film 4A regarding the resister devices 5 adjacently located each other along the y direction with the large substrate 2A is trimmed by heating in order to obtain the other adjusted resister film 4B. But, the side portion 6 is not located at the position adjacent to the already-adjusted resister film 4B. This process is called as the second trimming described before. The second trimming is performed to all pluralities of resister devices 5 formed on the large substrate 2A. These trimming processes avoid heating the surrounded area of the already-adjusted resister film 4B, namely the unit substrate 2B of which trimming is completed. Hence, it is possible to restrain fluctuation of the resister value due to re-heating the already-adjusted resister film 4B.

In the second trimming, the resister elements 5 adjacently located each other toward the x direction may be trimmed. Further, in the second trimming, the resister elements 5 adjacently located but sandwiching one or more the resister elements 5 toward the x or y direction may be trimmed. Then, un-trimmed resister elements 5 may be trimmed. These processes can restrain concretely heating a specific region of the large substrate 2A. Hence, it is possible to restrain re-heating the adjusted resister film 4B with accumulated heat in a specific region. But, in view of fast trimming, the resister elements 5 adjacently located each other toward the x or y direction may preferably be trimmed.

Accordingly, as a first advantage of trimming the resister film 4 only by heating without removing a part of it, the trimming only by heating can omit the process of forming a protection film such as a glass film for the resister film 4 in advance when a part of it is moved. As a second advantage, this process is superior in endurance against high voltage pulses since it can avoid excess damages such as micro crack of the resister film 4. Further, as a third advantage, it is possible to restrain reduction of the volume of the resister film 4. The process can be applied to the resister devices 1A and 1C described later used for a heavy electric load work and superior in endurance against pulses. Further, as a fourth advantage, trimming only by heating can avoid fluctuation of the resistance value of the resister device 5, caused by powders of conductive material of the resister film 4 flying in all directions and attaching to the trimmed resister device 5 when a part of the resister film 4 is removed.

(Forming Overcoating Film)

FIG. 2 (F) shows a state of forming an overcoating film 9 covering a part of the electrode 3 for a resister and the resister film 4. The overcoating film 9 is formed by depositing an epoxy resin paste with covering the resister film 4 via a screen printing, heating it and hardening it. The overcoating film 9 restrains deformation of the resister film 4 due to water in the atmosphere and protects the resister film from a mechanical shock. But, the overcoating film 9 is not necessarily formed. A powdered mixture of ruthenium oxide with gold or silver as a material of the resister film 4 includes a glass paste. Hence, ruthenium oxide and gold or silver having the heavy specific gravity are precipitated due to such inclusion when viscosity becomes lower by firing. After firing, a upper surface of the resister film 4 becomes a glass film, performing a function similar to the overcoating film 9. A material of the overcoating film 9 may be glass or resins more than epoxy resin such as an acryl resin. Further, the overcoating film 9 is penetrated into the concave portion 7, enhancing the adhesiveness of the overcoating film 9 with the substrate 2.

(First Partitioning)

FIG. 2 (G) shows a state of partitioning the large substrate 2A along the groove 2C for partitioning crossed by the electrode 3 for a resister among the grooves 2C for partitioning formed with horizontal and vertical directions on the substrate. In this partitioning (called as the first partitioning), the large substrate 2A is folded toward the direction where the groove 2C for partitioning is opened and partitioned to form the stripe shape substrate 2E. The first partitioning breaks the electrode 3 for a resister and the back side electrode 3A formed along the groove 2C for partitioning and exposes the end surface 2D (a broken out surface) of the substrate 2. Here, it is fear that the first partitioning may remove the end portions of the electrode 3 for a resister and the back side electrode 3A formed on the large substrate 2A from the substrate 2. Even if such end portions are removed from the stripe shape substrate 2E, however, silver is deposited to such removed portions of the electrode 3 for a resister and the back side electrode 3A by sputtering silver to the end surface 2D under a process of forming a second electrode described hereafter. Such deposition fixes the end portions of electrodes 3 and 3A to the substrate 2E, making it work as the resister 1A.

(Forming Second Electrode)

FIG. 2(H) is a diagram showing an elevation view corresponding to a plain view of FIG. 2(G) and completion of forming the second electrode. FIG. 2(H) shows a state of forming an end electrode 3B by depositing silver onto the end portion 2D with sputtering after the first partitioning. In this case, silver is also deposited onto the broken surface of the electrode 3 for a resister and the back side electrode 3A, electrically connecting the electrode 3 for resister and the end surface electrode 3B to the end surface electrode 3B and the back side electrode 3A respectively. As a result, a terminal electrode 3C is formed by integrating the exposed portion of the overcoating film 9 with the end electrode 3B and the back side electrode 3A among the electrodes 3 for a resister.

(Second Partitioning)

FIG. 2(I) shows a state of partitioning the stripe shape substrate 2E along the groove 2C for partitioning included in the substrate 2E. In this partitioning (called as a second partitioning), the substrate is partitioned to the unit substrate 2B by applying a stress the direction where the groove 2C for partitioning is opened. Here it is fear that the second partitioning may remove the end portion of back side electrode 3A formed with lying astride the vertical and horizontal directions of the grooves 2C for partitioning on the other surface (a backside surface) of the large substrate 2A from the unit substrate 2B. But, an broken area on a surface of the back side electrode 3A at the time of the second partitioning is small, making an impact small at the time of breaking. Hence, the second portioning hardly removes the back side electrode 3A from the unit substrate 2B. This second partitioning completes the resister device 1A.

(Plating)

After the above process, nickel plated layer (not shown in the figure) is formed on the surface of the terminal electrode 3C by barrel plating and solder plated layer (not shown in the figure) is formed on the nickel plated layer. In the barrel plating, many resister devices 1A are put into a basket dipped into a plating solution with metal grains called as dummy balls and plated by oscillating or rotating the basket and applying electricity to it. The nickel plated layer avoids alloying the solder plated layer with the terminal electrode 3C, called as solder leaching in the terminal electrode 3C. Further, the solder plated layer works as improving wettability of adhesive solder at the time of mounting the substrate onto a circuit plate. Here, time and/or current value for plating are arranged in order that the thicknesses of the nickel plated layer and solder plated layer become more than 3 μm and less than 12 μm respectively. If the thickness of the nickel plated layer is more than 3 μm, the plate layer is sufficiently formed. If he thickness of the nickel plated layer is less than 12 μm, the outside dimension of the resister 1A is exactly attained as intended. In particular, if the resister device 1A is sized to be small, the effect of such outside dimension becomes great. The method of manufacturing the resister device regarding the first embodiment is completed based on the above processes.

(Method of Manufacturing Resister Device of Second Embodiment)

The resister device 1C shown in FIG. 1(C) is formed by a method as a second embodiment. Here, the same numerical references are applied to the same components working as the same functions in the resister device 1A. FIG. 1(C) is a plain view of the resister device 1C in which the overcoating film 9 and the plated layer are omitted.

The resister device 1C is formed in a way that the shape of the resister film 4C winds like an S-shape on the substrate 2. The side portion 6A of the resister film 4C heated during trimming process is the outside end portion of the winded shape. Processes except forming a resister film and trimming it in the method of manufacturing the resister device 1A of the first embodiment are similarly applied to the method of manufacturing the resister device 1C of the second embodiment.

The resister film 4C is aligned by a screen printing during a process of forming the resister film. The configuration of an opened portion for print making is a winded S-shape. Forming a resister film in the method of manufacturing the resister device 1A of the first embodiment is similarly applied to this embodiment except the above process. The configuration of an opened portion for print-making a resister paste was a rectangular in the method of manufacturing the resister device 1A of the first embodiment. In trimming, two side portions 6A as an outside end of the winded resister film 4C are irradiated and heated by a laser beam with a stripe shape. Forming a resister film in the method of manufacturing the resister device 1A of the first embodiment is similarly applied to this embodiment except the above process. The method of manufacturing the resister device 1C regarding the second embodiment is completed based on the above processes.

Anti-surge property of the resister device 1C is superior to that of the resister devices 1A and 1B since the resister film 4C has a winded S-shape on the substrate 2. The resister device 1E described later also has superior anti-surge property. Further, in the resister device 1C, the side portion 6A of the resister film 4C heated during the trimming process is the outside end of the winded shape, restraining a drift as a fluctuation of the resistance value after trimming.

The winded shape of the resister film 4C does not include a slanted portion, but may include it so as to be the winded Z-shape. Further, the numbers of winding can be adjusted depending on an object of the resister device 1C. Further, a heated region may not be the outside end of the winded shape but the inside end of it.

(Method of Manufacturing Resister Device of Third Embodiment)

The resister device 1D shown in FIG. 1 (D) is formed by a method as a third embodiment. Here, the same numerical references are applied to the same components working as the same functions in the resister device 1A. FIG. 1(D) is a plain view of the resister device 1D in which the overcoating film 9 and the plated layer are omitted.

During trimming, a part of the resister film 4D in the resister 1D is removed so as to narrow a current path of the resister film 4D. This removing is performed before a region of the substrate 2 in the side portion 6B of the resister film 4D is heated. Processes except trimming in the method of manufacturing the resister device 1A of the first embodiment are similarly applied to the method of manufacturing the resister device 1D of the third embodiment. Then, covering the resister film 4D with a glass film is performed between forming a resister film and trimming in the method of manufacturing the resister device 1A of the first embodiment.

In the glass forming process, a glass paste is arranged to cover over the resister film 4D by a screen printing and fired (omitted in the figure.) Here, a part of the electrode 3 for a resister is exposed from the glass film to be a part of the terminal electrode 3C. The glass film mainly protects a non-trimmed part of the resister film 4D when a part of the resister film 4D is removed during trimming. The glass film may be formed only in the region where a trimming groove 11 is to be formed. Further, forming the glass film may be omitted if the resister film 4D is hardly broken.

During trimming in the method of manufacturing the resister device 1D of the third embodiment, a part of the glass film is evaporated by irradiating one of the sides of the resister film 4D with a laser beam. Next, a part of the resister film 4D is removed by moving the position of laser beam irradiation toward the center of the resister film 4D so as to narrow the current path of the resister film 4D. Such removing forms the trimming groove 11. Here, the trimming groove in FIG. 1 (D) includes a trace of a laser beam formed on the substrate 2. In forming the trimming groove 11, an operator makes the resistance value of the resister element 5C approach the target while measuring such value, and stops the irradiation of a laser beam if such value reaches the target. But, the resistance value possibly exceeds the target (over trimmed) due to drifting or delaying of stopping laser irradiation. In such case, in order to reduce the exceeded resister value, the side portion 6B is irradiated with a laser beam. The side portion 6B is adjacent to the area opposing to the other area of the resister film 4D where the trimming groove 11 is formed. Heating the side portion 6B is to frequently perform minor adjustment of the resistance value of the resister element 5C. The area for irradiation of a laser beam to the side portion 6B is not a stripe shape, but a circular shape or close to it as shown in FIG. 1D. Hence, the concave portion 7B has also a circular shape. This minor adjustment improves trimming accuracy. Here, the area for irradiation of a laser beam may be a stripe shape.

The side portion 6B is also irradiated with a laser beam on an area where the trimming groove 11 of the resister film 4D is formed. In such case, amount of fluctuated resistance value due to additional heating is small since other area of the resister film 4D has already been heated at the time of forming the trimming groove 11. Additional heating possibly widens a micro crack normally existed in the trimming groove 11, badly affecting anti-pulse property of the resister 1D. Hence, in order to avoid such affect, the region heated by laser beam irradiation is preferably the side portion 6B adjacent to the area opposing the other area of the resister film 4D where the trimming groove 11 is formed. The material of the overcoating film 9 is filled into the trimming groove 11, protecting the groove in the process of forming the overcoating film under the method of manufacturing the resister 1D of the third embodiment.

In the method of manufacturing the resister device 1D of the third embodiment, a part of the resister film 4D is removed in trimming before the region of the second substrate 2 at the side portion 6B of the resister film 4D is heated. But, such process order may be inversed. For example, when the resister value of the resister element 5C becomes lower than the target due to trimming by heating the region of the second substrate 2 at the side portion 6B of the resister film 4D, the resister film 4D is trimmed by the amount of this lowered value as micro adjustment by removing a part of the resister film 4D. In this case, the region for laser beam irradiation is preferably a stripe shape. The method of removing a part of the resister film 4D may be a so-called sandblast method in which fine insulated particles are stricken to such part with giving a mechanical impact to the part, more than the method of laser beam irradiation.

(Method of Manufacturing Resister Device of Fourth Embodiment)

The resister device 1E shown in FIG. 1(E) is formed by a method as a fourth embodiment. Here, the same numerical references are applied to the same components working as the same functions in the resister device 1A. FIG. 1 (E) is a plain view of the resister device 1E in which the overcoating film 9 and the plated layer are omitted.

During forming the resister 1E, removing a part of the resister film 4E makes the resister film 4 winded or accelerates winding of the film. Processes except forming a resister film and trimming in the method of manufacturing the resister device 1D of the third embodiment are similarly applied to the method of manufacturing the resister device 1E of the fourth embodiment.

The resister film 4E is aligned by a screen printing during a process of forming the resister film. In such case, an opened portion for printmaking is a shape called as a pseudo S-shape in which a closed portion at the lower side of an S-shape curve is opened. Forming a resister film in the method of manufacturing the resister device 1A of the first embodiment is similarly applied to this embodiment except the above process. In trimming, a trimming groove 11A is formed in an area having the pseudo S-shape of the resister film 4E in a way being similar to the method of manufacturing the resister device 1D of the third embodiment. This formation makes the resister film 4E have a S-shape (a winded shape.) Then, if over trimming is happened to cause an excess resister value, the two side portions 6C are irradiated and heated by a laser beam with a stripe shape in way being similar to trimming in the method of manufacturing the resister device 1D of the third embodiment. The two side portions 6C are the outside end of winding of the resister film 4E. The method of making the resister film 4E become an S-shape may be a sandblast method. In such case, laser beam irradiation is preferably a circular shape or close to such shape shown in FIG. 1 (D), but it may be a stripe shape as shown in FIG. 2(E).

In the method of manufacturing the resister device 1E of the fourth embodiment, the resister film 4E having the pseudo S-shape is formed during the process of forming the resister film. But, instead of the pseudo S-shape, the resister film 4E may have a perfect S-shape such as winding configuration in original. Then, a part of the resister film 4E may be removed in order to accelerate the state of the winding configuration. An advantage of forming the pseudo S-shape of the resister film 4E during the process of forming the resister film is the following. In the screen printing, forming the pseudo S-shape, which is relatively simple structure, with better reproductivity is easier than forming the complicated winding configuration with better reproductivity.

The resister devices 1A, 1B, 1C and 1E manufactured by the methods of the first, second, third and fourth embodiments include the substrate 2 and the resister films 4, 4C, 4D, and 4E contacting with a pair of electrodes 3 formed on the substrate 2. Further, these resister devices include the concave portions 7, 7A, 7B and 7C formed by laser beam irradiation onto the positions of side portions 6, 6A,6B and 6C of the resister films 4,4C,4D and 4E. Here, the concave portion may be formed by other method except heating such as molding the substrate 2 with including such concave shape. An advantage of forming these concave portions 7,7A and 7B is to enhance the adhesiveness of the overcoating film 9 with the substrate 2 since the overcoating film 9 is infiltrated into the inside of these concave portions 7,7A and 7B during forming the overcoating film 9.

The resister devices 1A, 1B, 1C and 1E and the methods of these devices have been explained in the above. But, various modifications can be available within the spirit of the invention. For example, the large substrate 2A is not an essential component so that the above mentioned processes can be applied to the unit substrate 2B. Hence, the first partitioning and second partitioning can be omitted since these are not essential. Further, the process of forming the overcoating film and plating can be omitted since they are not essential. If the resister devices 1A,1B, 1C, 1D and 1E are a so-called face down type of which an terminal electrode is only the electrode 3 for a resister, processes of forming the back electrode 3A during forming the first electrode and forming the second electrode can be omitted since they are not essential.

Further, in the method of manufacturing the resister devices 1A,1B, 1C, 1D and 1E as the above embodiments, the backside electrode 3A may be formed before plating. The resister films 4,4C, 4D and 4E may be formed before the electrode 3 for a resister is formed. In such case, the electrode 3 for a resister is formed on the upper surface of the end portions of the resister films 4, 4C,4D and 4E. Further trimming may be performed after forming the overcoating film 9.

During trimming, first, a specific row in the order of FIGS. 3(A),(B) and (C) or every other tow may be trimmed. Next, an adjacent row or every other row from upper or bottom such as FIGS. 3(A),(B) and (C) or every one or more than one rows may be trimmed.

The method of manufacturing a chip resister device including only one resister element 5 has been explained regarding trimming in the method of manufacturing the resister devices 1A,1B,1C, 1D and 1E of the embodiments. However, the above mentioned trimming can be applied to various resister devices such as a multiply-connected resister device including more than two resister elements 5, a network resister device, an electronic part as an integration of capacitances and coils with resister elements, and an electronic part as an integration of active elements like transistors with resister elements.

What is claimed is:

1. A method of manufacturing a resister device comprising:
trimming a resister element including a resister film in order to adjust a resister value of the resister element, the resister film contacting a pair of electrodes for a resister formed on a substrate, wherein a region of the substrate located in a position of a side portion and along with the resister film is heated in the trimming, the position being on a surface where the electrodes for a resister and the resister film are formed.

2. The method of manufacturing a resister device according to claim 1, wherein the heating is performed by laser beam irradiation.

3. The method of manufacturing a resister device according to claim 2, wherein a concave portion is formed in the side portion by the laser beam irradiation.

4. The method of manufacturing a resister device according to claim 1, wherein the heated region is both side portions of the resister film.

5. The method of manufacturing a resister device according to claim 2 wherein the heated region is both side portions of the resister film.

6. The method of manufacturing a resister device according to claim 3, wherein the heated region is both side portions of the resister film.

7. The method of manufacturing a resister device according to claim 1, wherein the resister film is formed in a way of winding on the substrate and the side portion is an outside end of the winding.

8. The method of manufacturing a resister device according to claim 2, wherein the resister film is formed in a way of winding on the substrate and the side portion is an outside end of the winding.

9. The method of manufacturing a resister device according to claim 3, wherein the resister film is formed in a way of winding on the substrate and the side portion is an outside end of the winding.

10. The method of manufacturing a resister device according to claim 4, wherein the resister film is formed in a way of winding on the substrate and the side portion is an outside end of the winding.

11. The method of manufacturing a resister device according to claim 1, wherein a part of the resister film is removed so as to narrow a current path of the resister film in addition to the heating during the trimming.

12. The method of manufacturing a resister device according to claim 2, wherein a part of the resister film is removed so as to narrow a current path of the resister film in addition to the heating during the trimming.

13. The method of manufacturing a resister device according to claim 3, wherein a part of the resister film is removed so as to narrow a current path of the resister film in addition to the heating during the trimming.

14. The method of manufacturing a resister device according to claim 4, wherein a part of the resister film is removed so as to narrow a current path of the resister film in addition to the heating during the trimming.

15. The method of manufacturing a resister device according to claim 7 wherein a part of the resister film is removed so as to narrow a current path of the resister film in addition to the heating during the trimming.

16. The method of manufacturing a resister device according to claim 11, wherein the part of the resister film is removed before the region of the substrate being heated.

17. The method of manufacturing a resister device according to claim 11 wherein removing the part of the resister film makes the resister film winded and/or accelerates the winded state.

18. The method of manufacturing a resister device according to claim 16 wherein removing the part of the resister film makes the resister film winded and/or accelerates the winded state.

19. A method of manufacturing a resister device comprising:
trimming a plurality of resister elements via heating in order to adjust a resister value of the resister elements that are formed on a large substrate and includes a resister film contacting a pair of electrodes for a resister, wherein the rimming includes:
obtaining an adjusted resister film via first trimming for adjustment by heating a side portion of the contact area of an un-adjusted resister film of which a resister value is not adjusted, contacted with a substrate;
obtaining other adjusted resister film via second trimming as heating a side portion of the unadjusted resister film being formed on the large substrate and not adjacent to the adjusted resister film for adjusting a resister value; and
repeating the second trimming.

20. A resister device comprising:
a substrate;
a pair of electrodes for a resister formed on the substrate;
a resister film being contacted with the pair of the electrodes; and
a concave portion formed in a side portion of the resister film on a surface of the substrate where the resister film is formed.
